(19) United States
(12) Patent Application Publication
(10) Pub. No.: US 2018/0353991 A1
(43) Pub. Date: Dec. 13, 2018

(54) GRAPHENE MATERIAL AND MANUFACTURING METHOD THEREOF

(71) Applicant: Chung Yuan Christian University, Taoyuan City (TW)

(72) Inventors: Wei-Song Hung, Taoyuan City (TW); Yun-Kang Yeh, New Taipei City (TW); Chien-Chieh Hu, Taoyuan City (TW); Kueir-Rarn Lee, Taoyuan City (TW); Juin-Yih Lai, Taoyuan City (TW)

(21) Appl. No.: 15/618,144

(22) Filed: Jun. 9, 2017

(51) Int. Cl. B05D 1/06; H01B 1/04; H05K 9/00; F28F 13/18

(52) U.S. Cl. CPC B05D 1/06; F28F 13/18; H05K 9/0081; H01B 1/04

(57) ABSTRACT

Disclosed are a graphene material and a manufacturing method thereof. A high molecule powder material is uniformly mixed with a blend of carbon black and graphene to form a material mixture. An electrostatic spraying operation is conducted by using an electrostatic spray gun to spray the material mixture of the high molecule powder material, carbon black, and graphene to a surface of a substrate so as to form a graphene coating layer such that the substrate supports the graphene coating layer. The high molecule powder material is at least 10 grains and the blended carbon black and graphene takes weight percentage of 1-10%. Carbon black is distributed in graphene so that mutual contact between carbon black and graphene and material properties of carbon black that show high conductivity makes electrical charges contained in the graphene material easy to move.

(a) Technical Field of the Invention

The present invention relates generally to technology concerning electrical conductivity, heat dissipation, and electromagnetic wave resistance of graphene, and more particularly to a graphene material and a manufacturing method thereof

(b) Description of the Prior Art

Graphene is formed from graphite. Graphene has a hexagonal honeycomb like planar structure constituted by carbon atoms and exhibits a thickness of one single carbon atom, so that graphene shows various unique material properties, such as electrical conductivity, heat dissipativity, light transmittability, and excellent mechanical properties, and is thus a nanometer material that is the thinnest and hardest, and has the smallest electrical resistivity in the world.

Before being properly processed, graphene is in a general form of flakes or minute chips, such as graphene powder, which has weak bonding power and is in a separate form, lacking a commercialized, mass-productive configuration, and may not be directly used in any application.

Media that bond graphene chips to form a graphene object are known. Such a bonded graphene object contains graphene chips that are randomly distributed. This affects the properties concerning electrical conductivity, heat dissipation, and resistance against electromagnetic waves.

Thus, it is desired to provide a graphene material that is formed by combining graphene chips or powder in such a way that the properties thereof are enhanced so as to be widely applicable to various fields.

The present invention is made to provide a solution to suit the above needs.

### SUMMARY OF THE INVENTION

An objective of the present invention is to provide a method form manufacturing a graphene material that shows excellent material properties.

To achieve the above objective, the present invention provides a method for manufacturing a graphene material that comprises: (a) uniformly mixing a high molecule powder material with a blend of carbon black and graphene to form a material mixture; (b) using an electrostatic spray gun to conduct an electrostatic spraying operation on the material mixture of the high molecule powder material, carbon black, and graphene to spray and apply to a surface of a substrate so as to form a graphene coating layer, wherein the substrate supports the graphene coating layer.

Another objective of the present invention is to provide a graphene material that shows excellent material properties.

To achieve the above objective, the present invention provides a graphene material, which is formed by coating a mixture of a high molecule powder material and blended carbon black and graphene on a surface of a substrate, wherein the high molecule powder material is at least 10 grains and the blended carbon black and graphene takes weight percentage of 1-10%.

As such, the material mixture is uniformly coated on the substrate and is bonded, through a strong bonding force, to the substrate to form a graphene material. The graphene material so made comprises carbon black distributed in graphene so that mutual contact between carbon black and graphene and material properties of carbon black that show relative low resistivity and relatively high conductivity makes electrical charges contained in the graphene material easy to move and thus exhibiting excellent properties of electrical conduction, heat dissipation, and resistance against electromagnetic waves, making it applicable to various fields.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a flow chart illustrating a manufacturing method according to the present invention.

FIG. 2 is a cross-sectional view illustrating a structure according to the present invention.

FIG. 3 is a diagram illustrating test result for heat dissipation property of the present invention.

FIG. 4 is a diagram illustrating test result for electromagnetic wave related property of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

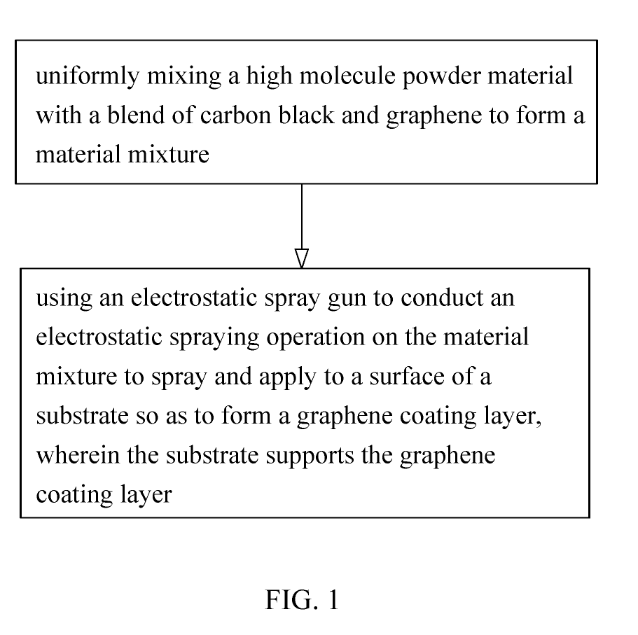

Referring to FIG. 1, the present invention provides a method for manufacturing a graphene material, which comprises:

(a) uniformly mixing a high molecule powder material with a blend of carbon black and graphene to form a material mixture; and

(b) using an electrostatic spray gun to conduct an electrostatic spraying operation on the material mixture of the high molecule powder material, carbon black, and graphene to spray and apply to a surface of a substrate so as to form a graphene coating layer, wherein the substrate supports the graphene coating layer.

The present invention provides a graphene material, which is formed by coating a mixture of a high molecule powder material and blended carbon black and graphene on a surface of a substrate, wherein:

the high molecule powder material is at least 10 grains; and

the blended carbon black and graphene takes weight percentage of 1-10%.

In an embodiment, the substrate comprises an aluminum plate.

In an embodiment, the carbon black used is conductive carbon black.

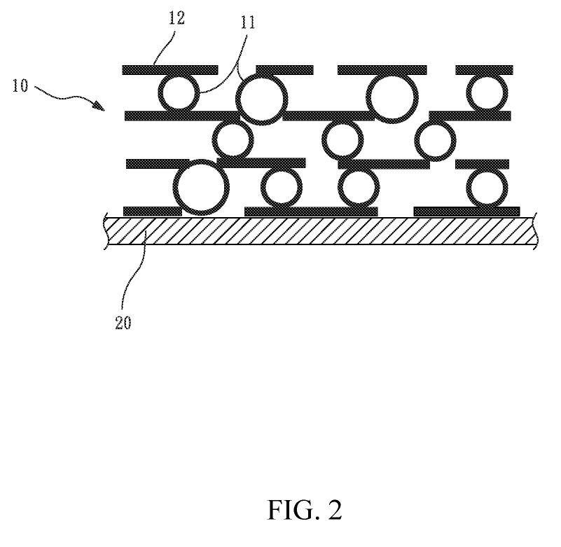

In an embodiment, the carbon black used has one of geometric shapes. As shown in FIG. 2, carbon black 11 has a circular shape in order to achieve mutual contact with graphene 12 for making electrical charges contained in the graphene material 10 of the present invention easy to move to thereby increasing electrical conductivity.

Referring to FIG. 2, according to the present invention, a high molecule powder material (not shown) and a blend of carbon black 11 and graphene 12 are uniformly mixed to form a material mixture, which is then uniformly coated on a substrate 20 so as to be bonded, with a strong bonding force, to the substrate 20 to form the graphene material 10. The graphene material 10 so manufactured is such that carbon black 11 is distributed among graphene 12 so that mutual contact between carbon black 11 and graphene 12 and the material properties of carbon black 11 that show relative low resistivity and relatively high conductivity make electrical charges contained in the graphene material 10 easy to move and thus exhibiting excellent properties of electrical conduction, heat dissipation, and resistance against electromagnetic waves, making it applicable to various fields

Tests conducted on the present invention reveal that an excessively added amount of the blend of carbon black 11 and graphene 12 would lead to destruction and separation of continuous phase of graphene 12 so as to hinder paths of electricity conduction and heat dissipation.

Results of tests of the present invention will be described to support that the graphene material according to the present invention exhibits excellent material properties:

(1) Electrical conductivity: as shown in FIG. 2, in the previous description, it has bee explained that in the graphene material 10 manufactured according to the present invention, carbon black 11 is distributed in graphene 12 so that through mutual contact between carbon black 11 and graphene 12 and the material properties of carbon black 11 that show relative low resistivity and relatively high conductivity, electrical charges contained in the graphene material are allowed to move more easily and thus exhibiting excellent properties of electrical conduction.

(2) Heat dissipation: tests of heat dissipation performance have been conducted on the graphene material according to the present invention.

Test conditions are as follows. Test subjects include graphene film material according to the present invention, high molecule powder material, carbon black, and graphene, wherein the high molecule powder material, carbon black, and graphene are individually coated on a surface of substrate, such as an aluminum plate, in the same way as that applied to the present invention.

A spot infrared heater is placed at a location distant from the aluminum plate by 3 centimeters and the light source is activated with power set at the third level for 1 minute to get stable, and then an infrared thermal imaging device is used to record readings of the back side.

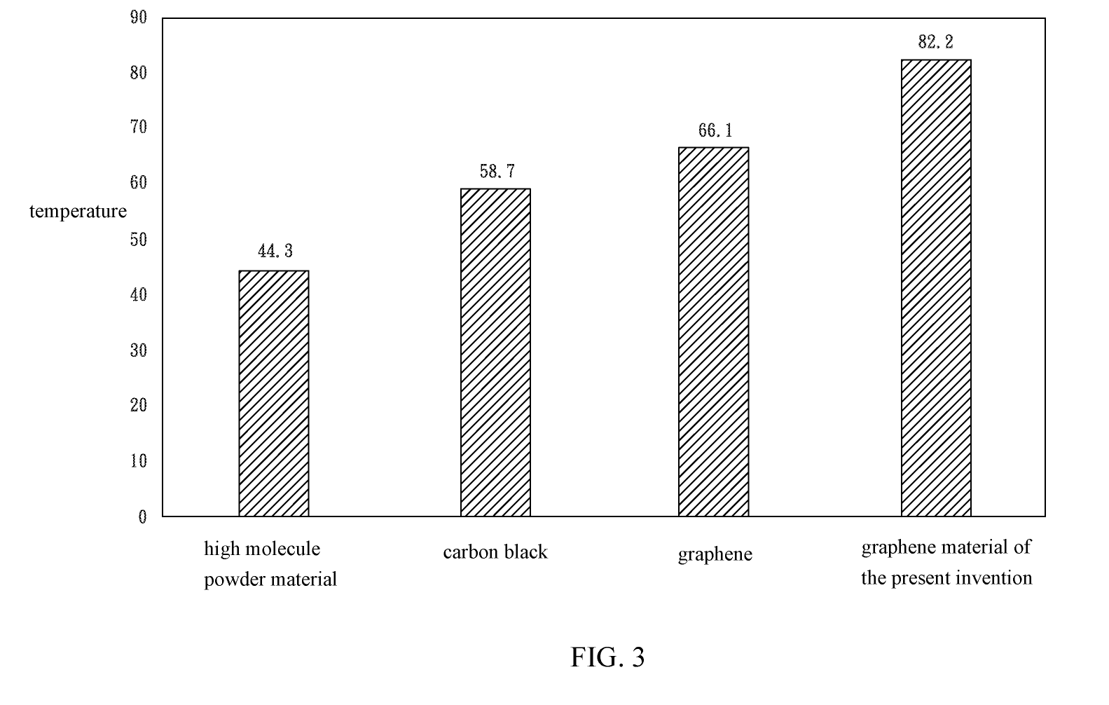

The results of test are shown in FIG. 3, where the temperature reading associated with the graphene material of the present invention is the highest, indicating the best property of heat dissipation.

(3) Resistance against electromagnetic wave: tests of electromagnetic wave have been conducted on the graphene material of the present invention in a local university.

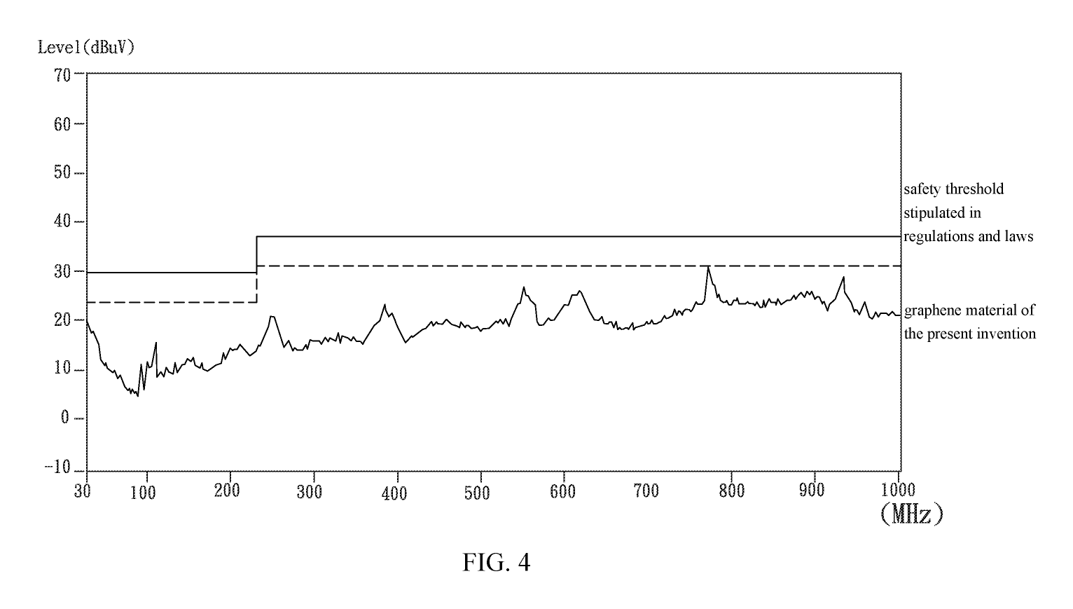

Test conditions are as follows. The graphene material according to the present invention is placed in a space that is free of electromagnetic waves and a test voltage is applied and an electromagnetic wave receiver is used to receive and detect electromagnetic waves of the graphene material of the present invention. The results of test are shown in FIG. 4. The electromagnetic wave levels detected by the electromagnetic wave receiver is far lower than a safety threshold stipulated in regulations and laws, indicating electromagnetic radiation level is low.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I claim:

1. A method for manufacturing a graphene material, comprising:
(a) uniformly mixing a high molecule powder material with a blend of carbon black and graphene to form a material mixture; and
(b) using an electrostatic spray gun to conduct an electrostatic spraying operation on the material mixture of the high molecule powder material, carbon black, and graphene to spray and apply to a surface of a substrate so as to form a graphene coating layer, wherein the substrate supports the graphene coating layer.

2. A graphene material, which is formed by coating a mixture of a high molecule powder material and blended carbon black and graphene on a surface of a substrate, wherein:
the high molecule powder material is at least 10 grains; and
the blended carbon black and graphene takes weight percentage of 1-10%.

3. The graphene material according to claim 2, wherein the substrate comprises an aluminum plate.

4. The graphene material according to claim 2, wherein the carbon black used is conductive carbon black.

5. The graphene material according to claim 2, wherein the carbon black used has one of geometric shapes.
